(19) United States
(12) Patent Application Publication
(10) Pub. No.: US 2012/0244381 A1
(43) Pub. Date: Sep. 27, 2012

(54) COATED ARTICLE HAVING ANTIBACTERIAL EFFECT AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); ZHI-JIE HU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/210,754

(22) Filed: Aug. 16, 2011

(30) Foreign Application Priority Data
Mar. 25, 2011 (CN) 201110073107.5

(51) Int. Cl. B21D 39/00; C23C 14/08; B32B 3/00; C23C 14/35; B32B 15/04; B32B 7/02

(52) U.S. Cl. 428/622; 428/469; 428/216; 428/336; 204/192.15

(57) ABSTRACT

A coated article is described. The coated article includes a substrate, a plurality of titanium dioxide layers and a plurality of copper layers formed on the substrate. Each titanium dioxide layer interleaves with one copper layer. One of the titanium dioxide layers forms an outermost layer of the coated article. A method for making the coated article is also described.

### CROSS-REFERENCE TO RELATED APPLICATIONS

This application is one of the four related co-pending U.S. patent applications listed below. All listed applications have the same assignee. The disclosure of each of the listed applications is incorporated by reference into the other listed applications.

| Attorney | | |
|---|---|---|
| Docket No. | Title | Inventors |
| US 37031 | COATED ARTICLE HAVING | HSIN-PEI |
| | ANTIBACTERIAL EFFECT AND METHOD | CHANG |
| | FOR MAKING THE SAME | et al. |
| US 39203 | COATED ARTICLE HAVING | HSIN-PEI |
| | ANTIBACTERIAL EFFECT AND METHOD | CHANG |
| | FOR MAKING THE SAME | et al. |
| US 39206 | COATED ARTICLE HAVING | HSIN-PEI |
| | ANTIBACTERIAL EFFECT AND METHOD | CHANG |
| | FOR MAKING THE SAME | et al. |
| US 40773 | COATED ARTICLE HAVING | HSIN-PEI |
| | ANTIBACTERIAL EFFECT AND METHOD | CHANG |
| | FOR MAKING THE SAME | et al. |

### BACKGROUND

1. Technical Field

The present disclosure relates to coated articles, particularly to a coated article having an antibacterial effect and a method for making the coated article.

2. Description of Related Art

To make the living environment more hygienic and healthy, a variety of antibacterial products have been produced by coating substrates of the products with antibacterial metal films. The metal may be copper (Cu), zinc (Zn), or silver (Ag). However, the metal ions within the metal films rapidly dissolve from killing bacterium, so the metal films have a short lifespan.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings like reference numerals designate corresponding parts throughout the several views.

FIG. 1 is a cross-sectional view of an exemplary embodiment of a coated article.

FIG. 2 is an overhead view of an exemplary embodiment of a vacuum sputtering device.

### DETAILED DESCRIPTION

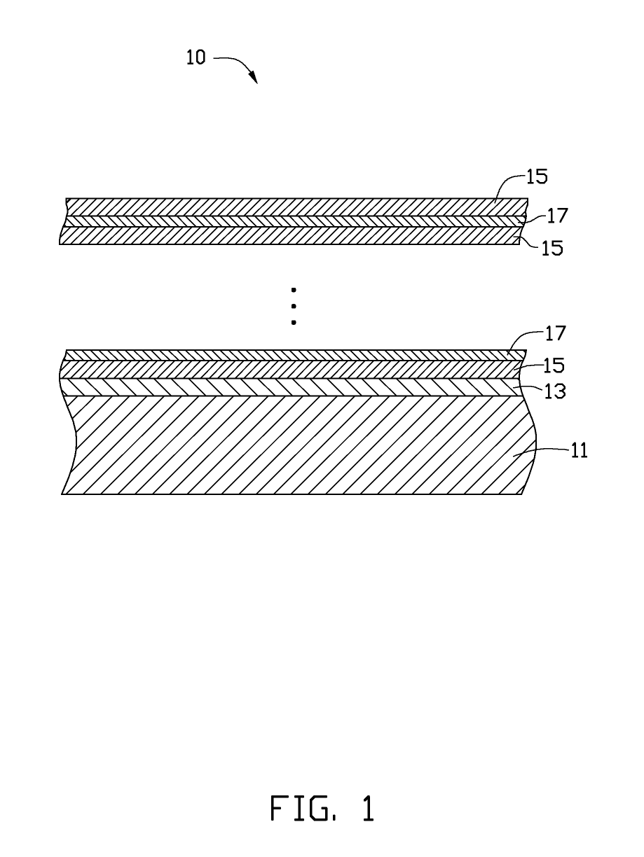

FIG. 1 shows a coated article 10 according to an exemplary embodiment. The coated article 10 includes a substrate 11, a bonding layer 13 formed on the substrate 11, a plurality of titanium dioxide (TiO₂) layers 15 and a plurality of copper (Cu) layers 17 formed on the bonding layer 13. Each TiO₂ layer 15 alternates/interleaves with one Cu layer 17. One of the TiO₂ layers 15 is directly formed on the bonding layer 13. Furthermore, one of the TiO₂ layers 15 forms the outermost layer of the coated article 10. Therefore, there is typically one more TiO₂ layer 15 than there are Cu layers 17. The total thickness of the TiO₂ layers 15 and the Cu layers 17 may be about 0.5 μm-1.2 μm. The total number of the TiO₂ layers 15 may be about 3 layers to about 11 layers. The total number of the Cu layers 17 may be about 2 layers to about 10 layers.

The substrate 11 may be made of stainless steel, but is not limited to stainless steel.

The bonding layer 13 may be a titanium (Ti) layer formed on the substrate 11 by vacuum sputtering. The bonding layer 13 has a thickness of about 50 nm-100 nm.

The TiO₂ layers 15 may be formed by vacuum sputtering. Each TiO₂ layer 15 may have a thickness of about 30 nm-120 nm.

The Cu layers 17 may be formed by vacuum sputtering. Each Cu layer 17 may have a thickness of about 40 nm-160 nm. The Cu layers 17 have an antibacterial property, the TiO₂ layers 15 inhibit the copper ions of the Cu layers 17 from rapidly dissolving, so the Cu layers 17 have long-lasting antibacterial effect. Furthermore, when irradiating, the TiO₂ layers 15 will produce strong oxidative free radical .OH and O. to kill bacterium, which further enhances and prolongs the antibacterial effect of the coated article 10.

A method for making the coated article 10 may include the following steps:

The substrate 11 is pre-treated, such pre-treating process may include the following steps:

The substrate 11 is cleaned in an ultrasonic cleaning device (not shown) filled with ethanol or acetone.

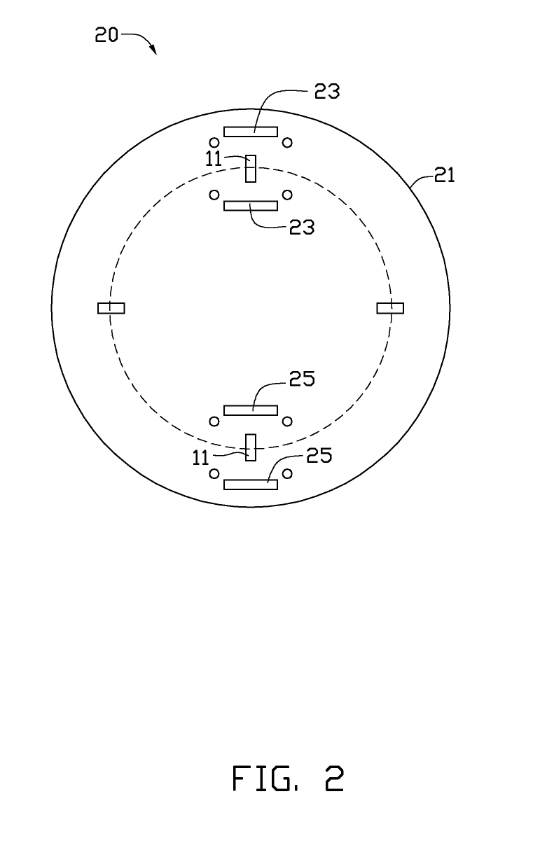

The substrate 11 is plasma cleaned. Referring to FIG. 2, the substrate 11 may be positioned in a coating chamber 21 of a vacuum sputtering device 20. The coating chamber 21 is fixed with titanium (Ti) targets 23 and copper (Cu) targets 25. The coating chamber 21 is evacuated to about 4.0×10⁻³ Pa. Argon gas (Ar) having a purity of about 99.999% may be used as a working gas and is fed into the coating chamber 21 at a flow rate of about 500 standard-state cubic centimeters per minute (sccm). The substrate 11 may have a bias voltage of about −200 V to about −350 V, then high-frequency voltage is produced in the coating chamber 21 and the argon gas is ionized to plasma. The plasma then strikes the surface of the substrate 11 to clean the surface of the substrate 11. Plasma cleaning of the substrate 11 may take about 3 minutes (min)-10 min. The plasma cleaning process enhances the bond between the substrate 11 and the bonding layer 13. The Ti targets 23 and the Cu targets 25 are unaffected by the pre-cleaning process.

The bonding layer 13 may be magnetron sputtered on the pretreated substrate 11 by using the titanium targets 23. Magnetron sputtering of the bonding layer 13 is implemented in the coating chamber 21. The inside of the coating chamber 21 is heated to about 50° C.-250° C. Argon gas may be used as a working gas and is fed into the coating chamber 21 at a flow rate of about 100 sccm-300 sccm. Power of about 5 kilowatt (KW) to about 12 KW is applied on the titanium targets 23, and the titanium atoms are sputtered off from the titanium targets 23 to deposit on the substrate 11 and form the bonding layer 13. During the depositing process, the substrate 11 may have a bias voltage of about −50 V to about −200 V. Depositing of the bonding layer 13 may take about 5 min-10 min.

One of the TiO₂ layers 15 may be magnetron sputtered on the bonding layer 13 by using the titanium targets 23. Magnetron sputtering of the TiO₂ layer 15 is implemented in the coating chamber 21. The internal temperature of the coating chamber 21 is maintained at about 50° C.-250° C. Oxygen (O₂) may be used as a reaction gas and is fed into the coating chamber 21 at a flow rate of about 50 sccm-200 sccm. Argon gas may be used as a working gas and is fed into the coating chamber 21 at a flow rate of about 100 sccm-300 sccm. Power of about 5 KW-12 KW is applied on the titanium targets 23, and the titanium atoms are sputtered off from the titanium targets 23. The titanium atoms and oxygen atoms are ionized in an electrical field in the coating chamber 21. The ionized titanium atoms then chemically react with the ionized oxygen to deposit on the bonding layer 13 and form the TiO₂ layer 15. During the depositing process, the substrate 11 may have a bias voltage of about −50 V to about −200 V. Depositing of the TiO₂ layer 15 may take about 5 min-15 min.

One of the Cu layers 17 may be magnetron sputtered on the TiO₂ layer 15 by using the Cu targets 25. Magnetron sputtering of the Cu layer 17 is implemented in the coating chamber 21. The internal temperature of the coating chamber 21 is maintained at about 50° C.-250° C. Argon gas may be used as a working gas and is fed into the coating chamber 21 at a flow rate of about 100 sccm-300 sccm. Power of about 2 KW-8 KW is applied on the Cu targets 25, and the Cu atoms are sputtered off from the Cu targets 25 to deposit on the TiO₂ layer 15 and form the Cu layer 17. During the depositing process, the substrate 11 may have a bias voltage of about −50 V to about −200 V. Depositing of the Cu layer 17 may take about 5 min-15 min.

The steps of magnetron sputtering the TiO₂ layer 15 and the Cu layer 17 are repeated about 1-9 times to form the coated article 10. In this embodiment, one more TiO₂ layer 15 may be magnetron sputtered on the Cu layer 17 and the TiO₂ layer 15 forms the outermost layer of the coated article 10.

Specific examples of making the coated article 10 are described as follows. The pre-treating process of ultrasonic and plasma cleaning the substrate 11 in these specific examples may be substantially the same as previously described so it is not described here again. Additionally, the magnetron sputtering processes of the bonding layer 13, TiO₂ layer 15, and Cu layer 17 in the specific examples are substantially the same as described above, and the specific examples mainly emphasize the different process parameters of making the coated article 10.

### Example 1

The substrate 11 is made of stainless steel.

Sputtering to form the bonding layer 13 on the substrate 11: the flow rate of Ar is 150 sccm; the substrate 11 has a bias voltage of −100 V; the internal temperature of the coating chamber 21 is 120° C.; sputtering of the bonding layer 13 takes 10 min; the bonding layer 13 has a thickness of 100 nm.

Sputtering to form TiO₂ layer 15 on the bonding layer 13: the flow rate of Ar is 150 sccm, the flow rate of O₂ is 70 sccm; the substrate 11 has a bias voltage of −100 V; the Ti targets 23 are applied with a power of 8 KW; the internal temperature of the coating chamber 21 is 120° C.; sputtering of the TiO₂ layer 15 takes 10 min; the TiO₂ layer 15 has a thickness of 50 nm.

Sputtering to form Cu layer 17 on the TiO₂ layer 15: the flow rate of Ar is 150 sccm; the substrate 11 has a bias voltage of −100 V; the Cu targets 25 are applied with a power of 5 KW; the internal temperature of the coating chamber 21 is 120° C.; sputtering of the Cu layer 17 takes 3 min; the Cu layer 17 has a thickness of 60 nm.

The step of sputtering the TiO₂ layer 15 is repeated 8 times, and the step of sputtering the Cu layer 17 is repeated 7 times.

### Example 2

The substrate 11 is made of stainless steel.

Sputtering to form the bonding layer 13 on the substrate 11: the flow rate of Ar is 150 sccm; the substrate 11 has a bias voltage of −100 V; the internal temperature of the coating chamber 21 is 120° C.; sputtering of the bonding layer 13 takes 5 min; the bonding layer 13 has a thickness of 50 nm.

Sputtering to form TiO₂ layer 15 on the bonding layer 13: the flow rate of Ar is 150 sccm, the flow rate of O₂ is 100 sccm; the substrate 11 has a bias voltage of −100 V; the Ti targets 23 are applied with a power of 10 KW; the internal temperature of the coating chamber 21 is 120° C.; sputtering of the TiO₂ layer 15 takes 15 min; the TiO₂ layer 15 has a thickness of 90 nm.

Sputtering to form Cu layer 17 on the TiO₂ layer 15: the flow rate of Ar is 150 sccm; the substrate 11 has a bias voltage of −100 V; the Cu targets 25 are applied with a power of 5 KW; the internal temperature of the coating chamber 21 is 120° C.; sputtering of the Cu layer 17 takes 5 min; the Cu layer 17 has a thickness of 100 nm.

The step of sputtering the TiO₂ layer 15 is repeated 5 times, and the step of sputtering the Cu layer 17 is repeated 4 times.

An antibacterial performance test has been performed on the coated articles 10 described in the above examples 1-2. The test was carried out as follows:

Bacteria was firstly dropped on the coated article 10 and then covered by a sterilization film and put in a sterilization culture dish for about 24 hours at a temperature of about 37±1° C. and a relative humidity (RH) of more than 90%. Secondly, the coated article 10 was removed from the sterilization culture dish, and the surface of the coated article 10 and the sterilization film were rinsed using 20 milliliter (ml) wash liquor. The wash liquor was then collected in a nutrient agar to inoculate the bacteria for about 24 hours to 48 hours at about 37±1° C. After that, the number of surviving bacteria was counted to calculate the bactericidal effect of the coated article 10.

The test result indicated that the bactericidal effect of the coated article 10 with regard to Escherichia coli, Salmonella, and Staphylococcus aureus was no less than 99%.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

1. A coated article, comprising:
a substrate; and
a plurality of alternating titanium dioxide layers and copper layers formed on the substrate, one of the titanium dioxide layers forming an outermost layer of the coated article.

2. The coated article as claimed in claim 1, further comprising a bonding layer formed between the substrate and the titanium dioxide.

3. The coated article as claimed in claim 2, wherein the bonding layer is a titanium layer and has a thickness of about 50 nm-100 nm.

4. The coated article as claimed in claim 2, wherein one of the titanium dioxide layers is directly formed on the bonding layer.

5. The coated article as claimed in claim 1, wherein the substrate is made of stainless steel.

6. The coated article as claimed in claim 1, wherein each titanium dioxide layer has a thickness of about 30 nm-120 nm.

7. The coated article as claimed in claim 1, wherein each copper layer has a thickness of about 40 nm-160 nm.

8. The coated article as claimed in claim 1, wherein total number of the titanium dioxide layers are about 3 layers to about 11 layers, and total number of the copper layers are about 2 layers to about 10 layers.

9. The coated article as claimed in claim 8, wherein the titanium dioxide layers and the copper layers have a total thickness of about 0.5 μm-1.2 μm.

10. A method for making a coated article, comprising:
providing a substrate;
forming a titanium dioxide layer on the substrate by vacuum sputtering, using oxygen as a reaction gas and using a titanium target;
forming a copper layer on the titanium dioxide layer by vacuum sputtering, using a copper target; and
alternately repeating the steps of forming the titanium dioxide layer and the copper layer to form the coated article with one of the titanium dioxide layers forming an outermost layer of the coated article.

11. The method as claimed in claim 10, wherein forming the titanium dioxide layer uses a magnetron sputtering method; the titanium target is applied with a power of about 5 KW-12 KW; the oxygen has a flow rate of about 50 sccm-200 sccm; uses argon as a working gas, the argon has a flow rate of about 100 sccm-300 sccm; magnetron sputtering of the titanium dioxide layer is conducted at a temperature of about 50° C.-250° C. and takes about 5 min-15 min.

12. The method as claimed in claim 11, wherein the substrate has a bias voltage of about −50V to about −200V during magnetron sputtering of the titanium dioxide layer.

13. The method as claimed in claim 10, wherein forming the copper layer uses a magnetron sputtering method; the copper target is applied with a power of about 2 KW-8 KW; uses argon as a working gas, the argon has a flow rate of about 100 sccm-300 sccm; magnetron sputtering of the copper layer is conducted at a temperature of about 50° C.-250° C. and takes about 5 min-15 min.

14. The method as claimed in claim 13, wherein the substrate has a bias voltage of about −50V to about −200V during magnetron sputtering of the copper layer.

15. The method as claimed in claim 10, further comprising a step of forming a bonding layer on the substrate before forming the titanium dioxide layers.

16. The method as claimed in claim 15, wherein forming the bonding layer uses a magnetron sputtering method, uses titanium target, the titanium target is applied with a power of about 5 KW-12 KW; uses argon as a working gas, the argon has a flow rate of about 100 sccm-300 sccm; magnetron sputtering of the bonding layer is conducted at a temperature of about 50° C.-250° C. and takes about 5 min-10 min.

17. The method as claimed in claim 16, wherein the substrate has a bias voltage of about −50V to about −200V during magnetron sputtering of the bonding layer.

18. The method as claimed in claim 15, further comprising a step of pre-treating the substrate before forming the bonding layer.

19. The method as claimed in claim 18, the pre-treating process comprises ultrasonic cleaning the substrate and plasma cleaning the substrate.
